(19) United States
(12) Patent Application Publication
(10) Pub. No.: US 2010/0019306 A1
(43) Pub. Date: Jan. 28, 2010

(54) Semiconductor Fabrication

(75) Inventors: Bohumil Lojek, Colorado Springs, CO (US); Mark A. Good, Colorado Springs, CO (US); Philip O. Smith, Colorado Springs, CO (US)

Correspondence Address: FISH & RICHARDSON P.C., PO BOX 1022, MINNEAPOLIS, MN, 55440-1022, US

(73) Assignee: ATMEL Corporation, San Jose, CA (US)

(21) Appl. No.: 12/239,504

(22) Filed: Sep. 26, 2008

Related U.S. Application Data
(60) Provisional application No. 61/083,806, filed on Jul. 25, 2008.

(51) Int. Cl. H01L 21/8247; H01L 21/322

(52) U.S. Cl. 257/316; 438/473; 257/E21.68

(57) ABSTRACT

This document discloses devices fabricated on a semiconductor substrate and methods of fabricating the same. The devices can be memory cells having a tunnel window that is defined by dry-etching oxide to expose the semiconductor substrate and growing a tunnel oxide layer on the exposed semiconductor substrate. The semiconductor substrate can be decontaminated and/or repaired by exposing the semiconductor substrate to an optical irradiated energy source having a predefined energy that is sufficient to break molecular bonds of the contaminants and exposing the semiconductor substrate to a temperature that is sufficient to recrystallize the crystal lattice of the substrate.

### CROSS-REFERENCE TO RELATED APPLICATIONS

This Application claims priority under 35 U.S.C. §119(e) to U.S. Provisional Application Ser. No. 61/083,806, titled “Semiconductor Processing” filed on Jul. 25, 2008, the disclosure of which is incorporated herein by reference.

### BACKGROUND

This specification relates to semiconductor fabrication.

Electronic devices are being developed that offer more capabilities, utilize less power and can be manufactured in small packages than those previously developed. For example, portable computing devices have evolved into comprehensive data devices that integrate the features of phones, personal digital assistants (PDAs) and computers. As the capabilities of these devices increase, so do their memory and power requirements. The increasing memory requirements of electronic devices, coupled with shrinking power budgets and packaging dimensions, require memory devices that offer more storage, with lower power consumption, and smaller physical dimensions. Therefore, many of these devices incorporate semiconductor memory cells because of the ability to fabricate high-density memory cells on a semiconductor substrate.

Semiconductor devices are fabricated in highly controlled environments (e.g., clean rooms) to prevent contamination of the materials used to fabricate the semiconductor devices. However, semiconductor substrates can still be contaminated or damaged prior to device fabrication or during device fabrication. If a semiconductor substrate is contaminated or damaged prior to processing, devices that are fabricated on the contaminated or damaged substrate will have lower quality than devices that are manufactured on an uncontaminated substrate. Similarly, if the semiconductor substrate is contaminated or damaged during device fabrication, then the quality of the device may be degraded.

An electrically erasable programmable read only memory (EEPROM) cell is a particular non-volatile memory cell that can be fabricated on a semiconductor substrate. EEPROM scaling is dependent on the size of the tunnel window that is defined for the device. The size of the tunnel window can depend, for example, on the process used to form the tunnel window. For example, smaller tunnel windows can be realized using dry-etch processing, rather than wet-etch processing. However, dry-etch processing can contaminate and damage the semiconductor substrate, resulting in lower quality devices.

### SUMMARY

This document discloses devices fabricated on a semiconductor substrate and methods of fabricating the same. The devices can be memory cells having a tunnel window that is defined by dry-etching oxide to expose the semiconductor substrate and growing a tunnel oxide layer on the exposed semiconductor substrate. The semiconductor substrate can be decontaminated and/or repaired by exposing the semiconductor substrate to an optical irradiated energy source having a predefined energy that is sufficient to break molecular bonds of the contaminants and exposing the semiconductor substrate to a temperature that is sufficient to recrystallize the crystal lattice of the substrate.

Particular implementations of the subject matter described in this specification can be implemented so as to realize one or more of the following advantages. Tunnel windows can be scaled by dry-etching the oxide from the semiconductor substrate. Memory cells can be scaled because smaller tunnel windows can be realized. Damaged semiconductor substrates can be repaired by exposing the semiconductor substrate to an atmosphere at a predefined temperature. Contaminated semiconductor substrates can be decontaminated by exposing the substrate to an optical irradiated energy source. The decontamination and repair can be performed in a single processing step. These advantages can be realized separately or in combination in various implementations.

The details of one or more embodiments of the subject matter described in this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is a cross-sectional view of an example non-volatile memory cell.

FIGS. 2A-2L are cross-sectional views of an example memory cell at stages throughout an implementation of non-volatile cell fabrication.

FIG. 3 is a flow chart of an example process of decontaminating and repairing a semiconductor substrate.

FIG. 4 is a flow chart of another example process of decontaminating and repairing a semiconductor substrate.

FIG. 5 is a flow chart of an example process of fabricating a memory cell.

Like reference numbers and designations in the various drawings indicate like elements.

### DETAILED DESCRIPTION

Devices can be fabricated on a semiconductor substrate through a series of processing steps. For example, a non-volatile memory cell (“memory cell”) can be fabricated through processing steps that prepare the semiconductor substrate for depositing, implanting, or otherwise forming elements of the memory cell in and on the semiconductor substrate. In some situations, these processing steps can result in deposition of contaminants on the semiconductor substrate. The processing steps can also damage the semiconductor substrate. The damage to the semiconductor substrate can be, for example, damage to a crystal lattice structure of the semiconductor substrate. If processing continues with a contaminated and/or damaged semiconductor substrate the quality of the memory cell may be degraded. Thus, decontaminating and repairing the semiconductor substrate can result in a higher quality memory cell. While decontamination and repair of a semiconductor substrate is discussed with reference to memory cell fabrication, semiconductor substrate decontamination and repair can be performed independent of a device being formed.

In some implementations, a semiconductor substrate can be decontaminated by exposing the semiconductor substrate to UV light having sufficient energy to break the molecular bond of the contaminants that are on the semiconductor substrate. The energy required to break the molecular bond of the contaminants can depend on the contaminant bonds present (e.g., 347 kJ/mol for a carbon-carbon (“C—C”) bond, 413 kJ/mol for a carbon-hydrogen (“C—H”) bond, and 301 kJ/mol for a silicon-carbon (“Si—C”) bond). The required energy can be applied, for example, by a rapid thermal processing (RTP) unit that can include a UV energy source. Once the contaminant molecular bonds are broken, the RTP unit can be maintained at a pre-determined temperature so that the contaminants can be volatilized into the atmosphere of the RTP unit. In turn, the contaminants can be removed when the atmosphere of the RTP unit is cycled.

In addition to removing the contaminants from the semiconductor substrate, any damage that may have occurred to the lattice of the silicon during dry-etching can be repaired by maintaining the substrate at a pre-determined temperature for a defined period of time (e.g., 1150 degrees Celsius for 10-15 seconds). Maintaining the substrate at the pre-determined temperature can facilitate recrystallization of the silicon lattice thereby repairing the damage to the silicon.

The decontamination and repair process can be used, for example, in an EEPROM memory cell fabrication process to facilitate dry-etching of tunnel windows. Smaller tunnel windows can be realized with dry-etching than wet-etching. Therefore, smaller EEPROM memory cells can be realized with dry-etching because the size of an EEPROM memory cell depends on the size of the tunnel window. While EEPROM memory cell scaling can be achieved by dry-etching the tunnel window, dry-etching can contaminate and damage the semiconductor substrate, thereby reducing the quality of the EEPROM memory cell. In some implementations, the decontamination and repair process can be used to remove the contaminants from the substrate and repair the substrate so that the tunnel window can be dry-etched.

Throughout this document, the decontamination and repair of a semiconductor substrate is discussed with reference to memory cell fabrication, and particularly tunnel window formation. However, the decontamination and repair process can be used to decontaminate and repair semiconductor substrates, regardless of the application. For example, a semiconductor substrate can be decontaminated and repaired prior to performing any fabrication processing or at other times during the fabrication processing.

### §1.0 Example Non-Volatile Memory Cell

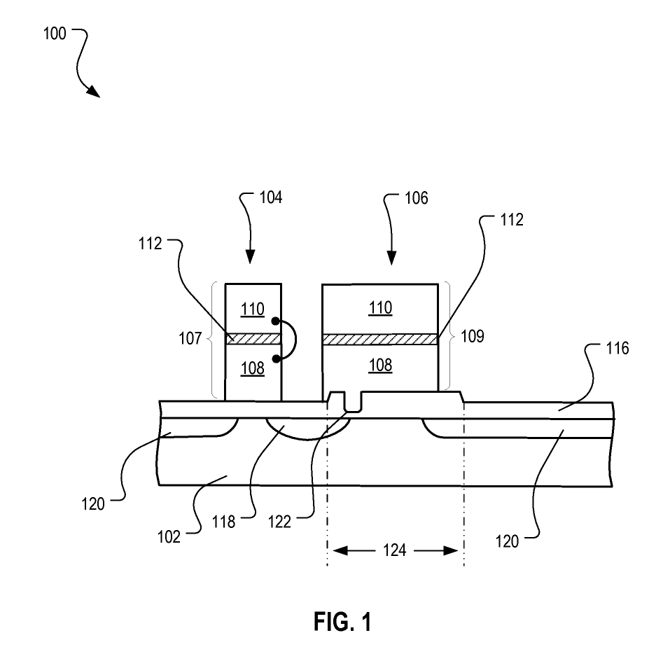

FIG. 1 is a cross-sectional view of an example non-volatile memory cell 100 (“memory cell”). The memory cell 100 can be, for example, an EEPROM memory cell. In some implementations, the memory cell 100 can be fabricated with a process that includes a semiconductor decontamination and/or repair routine. The memory cell 100 has a semiconductor substrate 102. The semiconductor substrate 102 can be silicon or any other appropriate semiconductor material.

The memory cell 100 can include a select transistor 104 and a memory transistor 106. A select transistor gate structure 107 can define the select transistor 104. Similarly, a memory gate structure 109 can define the memory transistor 106. The select transistor gate structure 107 and the memory gate structure 109 can include a first poly 108 and a second poly 110 that are separated by a first dielectric layer 112. The first poly 108 in the memory gate structure 109 can be a floating gate, while the second poly 110 can be a control gate for the select transistor 104 and memory transistor 106. The first poly 108 and second poly 110 of the select transistor gate structure 107 can be connected, as shown, so that the select transistor 104 functions as a single gate transistor, rather than a floating gate transistor. Alternatively, the select transistor 104 can be a single gate transistor.

The first poly 108 and the second poly 110 can be formed, for example, from polysilicon, or any other appropriate gate material. The first dielectric layer 112 can be formed, for example, from oxide-nitride-oxide or any other appropriate dielectric layer.

The first poly 108 and second poly 110 can be positioned on a structured oxide layer 116. A source 118 and drains 120 can be defined in the semiconductor substrate 102 for the select transistor 104 and the memory transistor 106. The source 118 and drains 120 are defined, for example, with p-regions that are implanted in an n-type semiconductor substrate, resulting in a p-type memory cell. In other implementations, the source 118 and drains 120 are defined with n-regions that are implanted in a p-type semiconductor substrate, resulting in an n-type memory cell.

The structured oxide layer 116 can be, for example, silicon dioxide or any other appropriate oxide layer. The structured oxide layer 116 can have a thickness that varies from approximately 19 Å to approximately 280 Å and defines a tunnel window 122. The size of the tunnel window 122 affects the scaling of the memory cell 100 because required gate dimensions (e.g., poly dimensions) are proportional to tunnel window dimensions. The size of the tunnel window 122 can depend, for example, on the etching process used to form the tunnel window, as discussed below.

### §2.0 Example Memory Cell Fabrication

A memory cell 100 can be fabricated, for example, by forming elements (e.g., depositing gate material, growing oxide layers, etc.) on the semiconductor substrate 102 and selectively removing (e.g., etching) unwanted material from the semiconductor substrate 102. The formation of elements on the semiconductor substrate 102 and the removal of material from the semiconductor substrate 102 can result in carbon contamination of the semiconductor substrate 102 and/or damage to the semiconductor substrate 102. In some implementations, the semiconductor substrate 102 can be decontaminated and repaired, for example, after removing (e.g., etching) material from the semiconductor substrate 102. In some implementations, the memory cell can be fabricated by forming an oxide layer on the semiconductor substrate, forming a tunnel window in the oxide layer, forming gates on the oxide layer, and forming sources and drains in the semiconductor substrate, as discussed below.

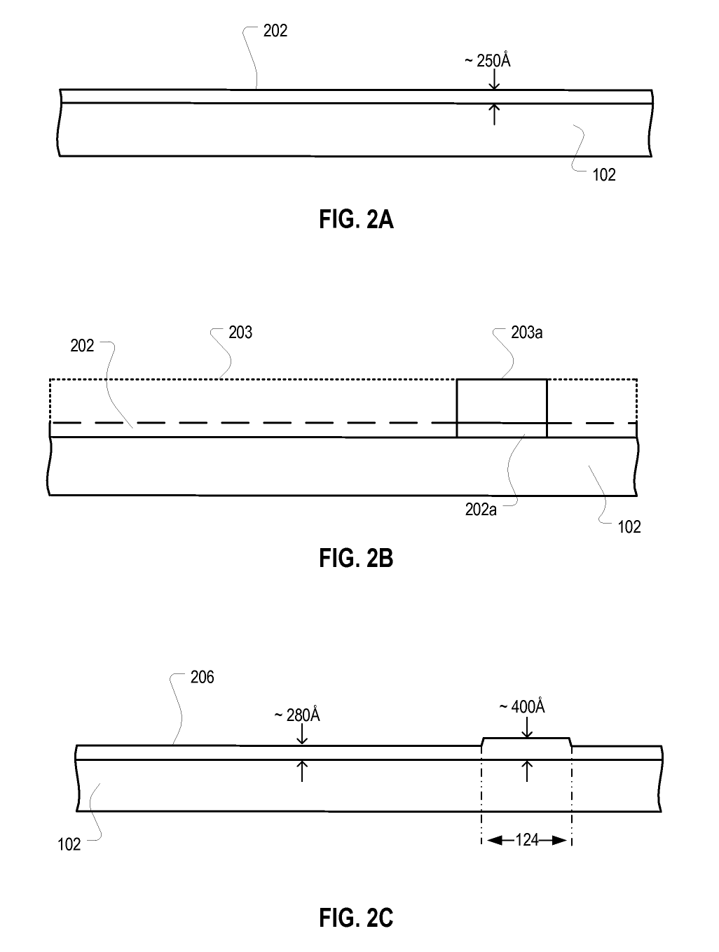

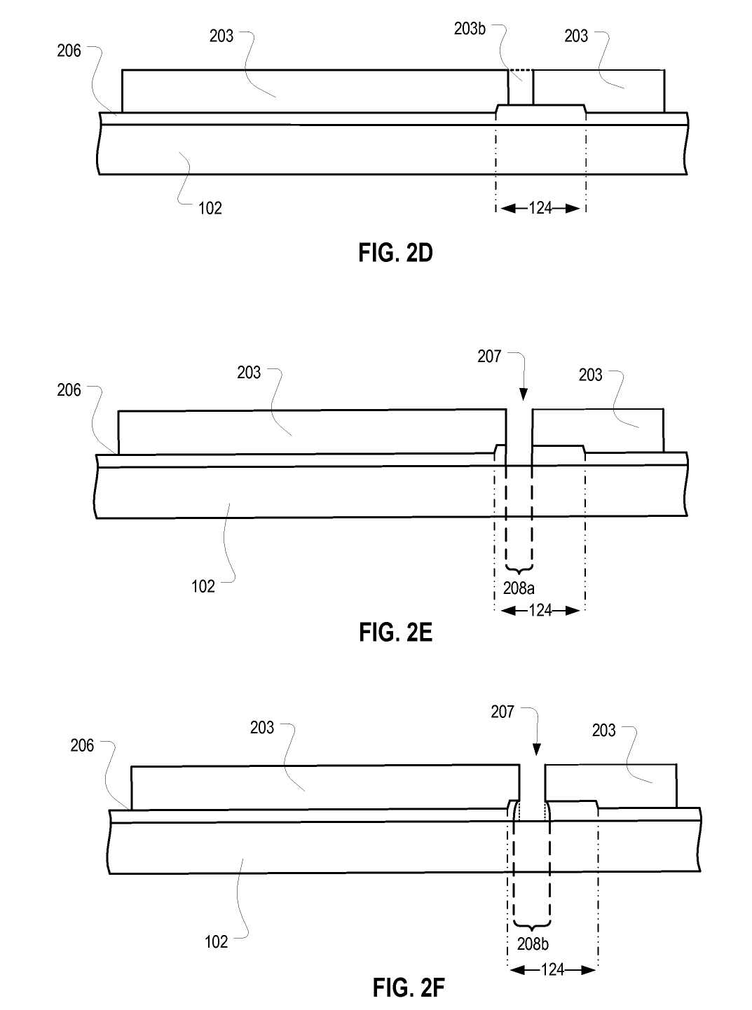

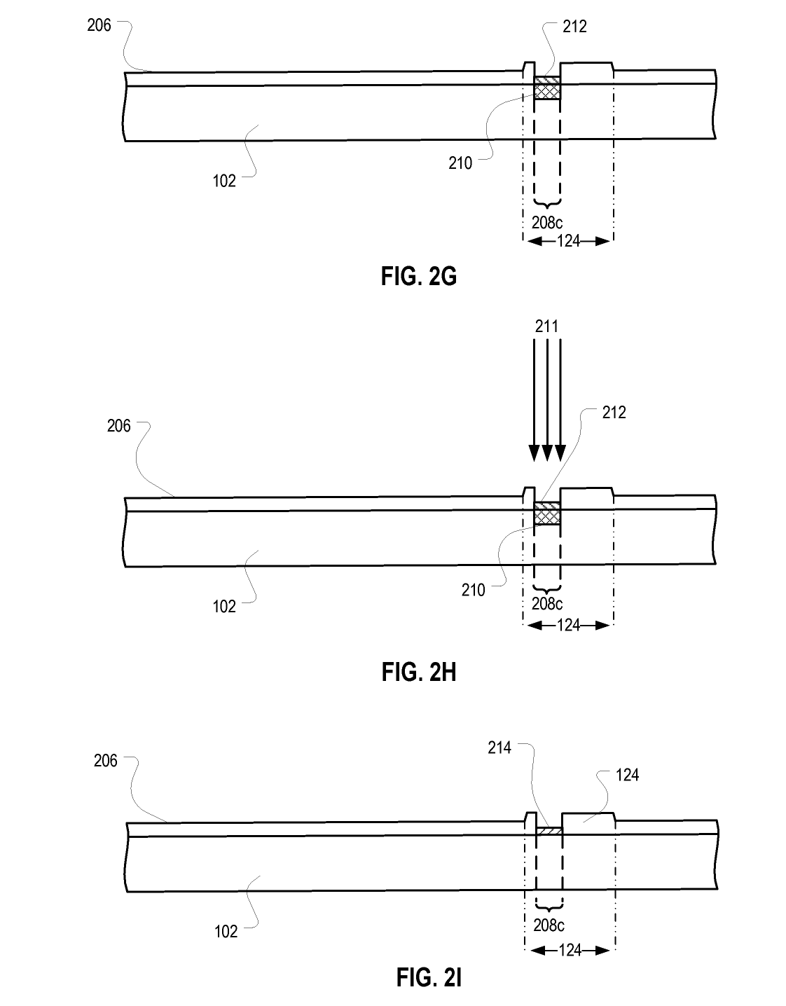

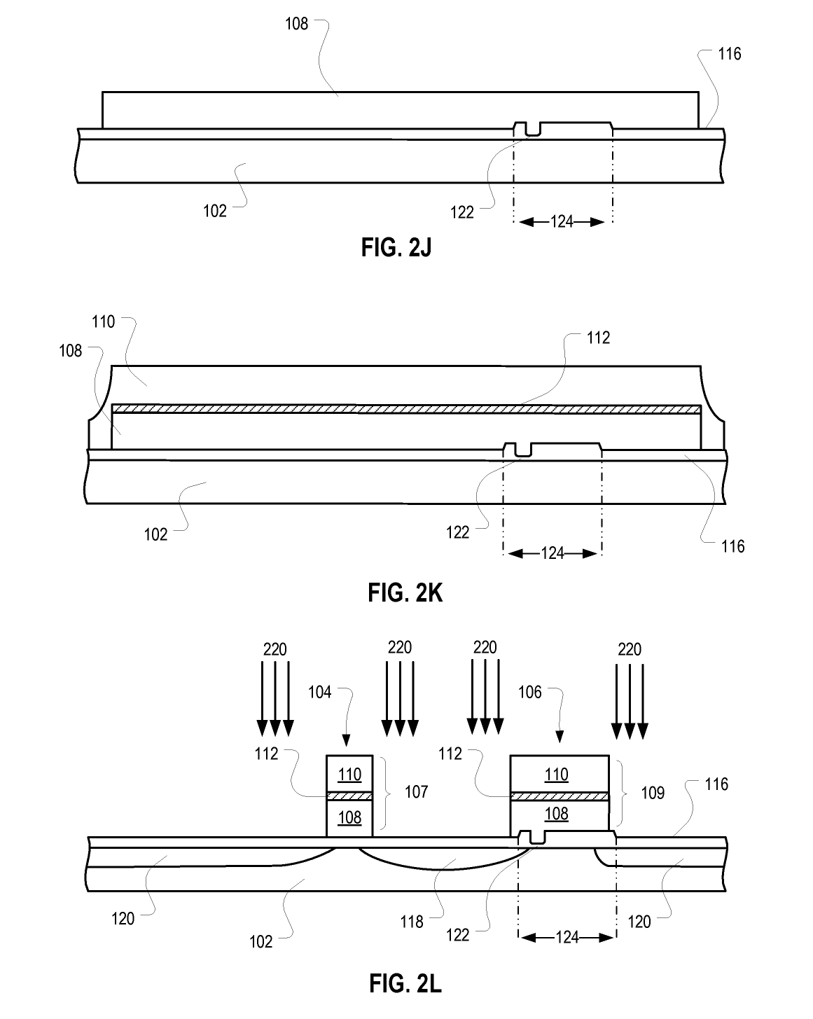

FIGS. 2A-2L are cross-sectional views of an example memory cell 100 at stages throughout an example memory cell fabrication process. While the cross-sectional views are presented in a particular order for example purposes, the memory cell fabrication is not limited to the order presented.

### §2.1 Example Oxide Formation

Referring to FIG. 2A, the structured oxide layer 116 of FIG. 1 can be fabricated, for example, by growing an oxide layer on the semiconductor substrate 102, selectively removing portions of the oxide layer, and growing additional layers of oxide on the semiconductor substrate, as discussed below.

Referring to FIG. 2A, an initial oxide layer 202 can be grown on the semiconductor substrate 102. The initial oxide layer 202 contributes to a final thickness of a raised oxide portion 124 in FIG. 1. The initial oxide layer 202 can be silicon dioxide or any other appropriate oxide layer. The initial oxide layer 202 can be formed, for example, by thermal oxidation of the semiconductor substrate 102, or any other appropriate method. The initial oxide layer 202 can be grown, for example, to be approximately 250 Å-400 Å thick.

Referring to FIG. 2B, photoresist 203a can be applied to a portion 202a of the initial oxide layer 202 where a memory transistor (e.g., memory transistor 106) will be located. For example, photoresist 203 can be applied to the entire initial oxide layer 202. A mask can be used to selectively remove the photoresist 203 from the initial oxide layer 202. For example, the photoresist 203 that is not covered by the mask can be removed with photolithography, while the photoresist 203a that is protected by the mask remains on the portion 202a of the initial oxide layer 202 where the memory transistor will be located.

Once the photoresist 203 is selectively removed such that the photoresist 203a remains, the initial oxide layer 202 can be etched. The etching process removes the initial oxide layer 202 that is not protected by the remaining photoresist 203a. Accordingly, the portion 202a of the initial oxide layer 202 is not etched and remains on the semiconductor substrate 102. The photoresist 203a is then removed to expose the remaining portion 202a of the initial oxide layer 202. Further processing can be performed on the remaining portion 202a of the initial oxide layer 202 to create, for example, the structured oxide layer 116 of FIG. 1, as discussed below.

Referring to FIG. 2C, a second oxide layer 206 can be grown on the semiconductor substrate 102 and the remaining initial oxide layer 202a to create an oxide layer having a raised oxide portion 124 (e.g., structured oxide layer 116 of FIG. 1). The second oxide layer 206 grows at a slower rate on the remaining portion 202a of the initial oxide layer 202 than on the semiconductor substrate 102. Accordingly, the second oxide layer 206 that is grown on the semiconductor substrate 102 can be approximately 220 Å thick, while the raised oxide portion 124 can be, for example, approximately 280 Å thick.

### §2.2 Example Tunnel Window Formation

A tunnel window 122 can be formed in the raised oxide portion 124, as shown in FIG. 1. The tunnel window 122 is a thin layer of oxide on the semiconductor substrate that can facilitate movement of electrons between a well in the semiconductor substrate and a floating gate of the memory transistor. Tunnel windows can be formed in active regions that are defined in the semiconductor substrate 102. The active regions can be defined, for example, by isolation regions that are formed in the semiconductor substrate 102. The isolation regions can be formed, for example, by shallow trench isolation, local oxidation of silicon, or any other appropriate isolation technique. The tunnel window can be formed by etching the raised oxide portion 124 to expose the semiconductor substrate 102 and growing a thin layer of oxide on the exposed semiconductor substrate 102.

### §2.2.1 Example Tunnel Window Etching

Referring to FIG. 2D, in some implementations, photoresist 203 can be applied to the second oxide layer 206 and the raised oxide portion 124 to protect the second oxide layer 206 and the covered portion of the raised oxide portion 124 during the etching process. Photolithography can be used to remove a portion 203b of the photoresist 203 that is located over the raised oxide portion 124 where the tunnel window 122 will be formed.

For example, a mask can be positioned over the semiconductor substrate 102 so that a mask opening corresponding to the tunnel window is positioned over the raised oxide portion 124. The mask can be exposed to ultraviolet light from, for example, a stepper. In turn, the light can propagate through the opening in the mask and define a pattern in the photoresist 203 located beneath the mask opening (e.g., portion 203b) to expose the raised oxide portion 124.

Referring to FIG. 2E, after the portion 203b of the photoresist 203 is exposed to the ultraviolet light, an opening 207 is defined over the raised oxide portion 124. In turn, an etching process can remove the raised oxide portion 124 that is exposed by the opening 207. The etching process defines an area 208a of the tunnel window 122 in the raised oxide portion 124 by exposing the semiconductor substrate 102. The etching can be performed, for example, using wet-etching or dry-etching processes.

Wet-etching can be performed, for example, by applying liquid chemicals to an oxide layer or other material to be removed from a semiconductor substrate 102. The chemicals disassociate the material that is not protected by photoresist 203 from the semiconductor substrate 102. Wet-etching can remove the material from the semiconductor substrate 102 without significantly damaging the semiconductor substrate 102. However, wet-etching is not an anisotropic (e.g., directional) etching process. Therefore, the chemicals that are used for wet-etching can diffuse laterally and remove a portion of the material that is protected by photoresist 203.

FIG. 2F shows an example area 208b set off by dashed lines that can result from a wet-etching process. A portion of the raised oxide portion 124, between the solid line and the dotted line that was protected by the photoresist 203 has been etched. Thus, a larger area 208b of the raised oxide portion 124 has been etched than that exposed by the opening 207. In some situations, wet-etching may not be able to achieve nanometer scale etching because the lateral etching may limit the minimum size of the area that can be etched.

Dry-etching can be performed, for example, by exposing the oxide layer or other material to plasma ions that can remove the material from the semiconductor substrate 102. The plasma can include, for example, reactive gases (e.g., fluorocarbons, chlorine, oxygen, etc.).

Referring to FIGS. 2G and 2E, dry-etching is a more anisotropic etching process than wet-etching. Therefore, less lateral etching is experienced with dry-etching, than wet-etching. Accordingly, a smaller area can be etched into the raised oxide portion 124 using dry-etching, rather than wet-etching. For example, dry-etching can result in an area 208c that approximates the size of area 208a. Accordingly, dry-etching can result in nanometer scale (e.g., less than 10 nanometer diameter) etching, whereas wet-etching cannot.

Although dry-etching can be used to achieve smaller etched areas, the semiconductor substrate 102 can be exposed to the plasma ions after the material has been removed from the semiconductor substrate 102. The impact of the plasma ions can result in a damaged portion 210 of the semiconductor substrate 102. For example, in some situations, the plasma ions can damage the crystal lattice structure of the semiconductor substrate 102. If the damaged portion 210 of the semiconductor substrate 102 is not repaired, the quality of oxide that can be grown on the damaged portion 210 of the semiconductor substrate 102 may be degraded.

Dry-etching can also result in the production of various polymer and carbon based contaminants 212 at the surface of the semiconductor substrate 102 (e.g., the surface of the semiconductor substrate 102 located under the tunnel window 122). For example, organic materials in the photoresist 203 can interact with the plasma ions to create the polymer contaminants that can be deposited on the semiconductor substrate 102. If these polymer contaminants 212 are not removed, they can also affect the quality of oxide that can be grown on the exposed portion of the semiconductor substrate 102.

### §2.2.2 Example Semiconductor Decontamination and Repair

In some implementations, a contaminated and/or damaged semiconductor substrate 102 can be decontaminated and repaired following dry-etching. For example, the polymer contaminants deposited by the dry-etching as well as other contaminants that might have been deposited on the semiconductor substrate 102 can be removed. Similarly, lattice damage caused by the dry-etching process or any other processing can be repaired. Therefore, dry-etching can be used to realize a smaller tunnel window and, in turn, a smaller memory cell (e.g., memory cell 116) while reducing the contamination and damage that may result from the dry-etching.

Referring to FIG. 2H, in some implementations, the semiconductor substrate 102 can be decontaminated by exposing the semiconductor substrate 102 (e.g. the portion of the semiconductor substrate 102 below the tunnel window 122) to an optical irradiated energy source 211 that has sufficient energy to break the molecular bonds of the contaminants. For example, the semiconductor substrate 102 can be placed in a rapid thermal processing (“RTP”) unit to be decontaminated. The RTP unit can have an optical irradiated energy source that can generate the energy required to break the molecular bonds of the contaminants. In some implementations, the optical irradiated energy source can be an ultraviolet (“UV”) source, a combination of UV and infrared (“IR”) energy sources, or any other energy source capable of generating the energy required to break the molecular bonds.

The energy required to break the molecular bonds of the contaminants can depend, for example, on the contaminants that are present on the semiconductor substrate. For example, if the contaminants contain a C—C bond, then about 347 kJ/mol of energy can be required to break the bond. Similarly, about 413 kJ/mol of energy can be required to break a C—H bond and about 301 kJ/mol can be required to break a Si—C bond. In some implementations, the UV source in the RTP unit can produce the energy required to break molecular bonds of contaminants that are located on the semiconductor substrate 102. While particular contaminant molecular bonds are provided, other molecular bonds can be present and the energy required to break each molecular bond can be identified.

Once the molecular bonds of the contaminants are broken and volatilized, the atmosphere flowing through the RTP unit can absorb the contaminants. In some implementations, the absorption of contaminants into the atmosphere of the RTP unit can be enhanced by increasing the temperature of the semiconductor substrate in the RTP unit and maintaining a predefined temperature. In some implementations, the temperature of the RTP unit can be increased by the optical irradiated energy source, which, in turn, can increase the temperature of the semiconductor substrate in the RTP unit. For example, an RTP unit that includes tungsten and halogen lamps can heat the atmosphere of the RTP unit to about 1100 degrees Celsius within several seconds.

The predefined temperature can be maintained by the optical irradiated energy source or a separate heating source to facilitate absorption of the contaminants into the atmosphere. In some implementations, the predefined temperature can be within a range of about 1100-1200 degrees Celsius. As the contaminants absorb into the atmosphere, the atmospheric gas can be cycled so that the gas that has absorbed the contaminants can be removed from the RTP unit.

In some implementations, the atmosphere of the RTP unit can have an oxygen concentration that is less than about 50 parts per million (“ppm”). Maintaining an oxygen concentration less than about 50 ppm in the atmosphere of the RTP unit can limit oxidation of the exposed semiconductor substrate 102. The remainder of the atmosphere can be, for example, nitrogen, argon, or any other non-reactive gas.

In some implementations, the semiconductor substrate 102 can also be exposed to the predefined temperature to repair damage to the semiconductor substrate 102. For example, the crystal lattice at the surface of the semiconductor substrate 102 can re-crystallize when it is exposed to an atmosphere at about 1150 degrees Celsius for approximately 10 to 15 seconds. Thus, damage that may have been caused by dry-etching or other processing can be repaired. While a particular temperature and exposure time is provided, other combinations of temperature and exposure time can be used to facilitate re-crystallization of the semiconductor substrate crystal lattice.

Once the exposed semiconductor substrate 102 (e.g., the portion of the semiconductor substrate 102 below the tunnel window 122) has been cleaned and repaired, tunnel oxide 214 can be grown on the exposed semiconductor substrate 102. The tunnel oxide 214 completes the formation of the tunnel window 122 and the structured oxide layer 116. In some implementations, the tunnel oxide 214 can range from about 19 Å-90 Å thick. Other thicknesses can also be used, depending on the application. An example of a completed structured oxide layer 116 is shown in FIG. 2J.

### §2.3 Example Gate Formation

In some implementations, after the structured oxide layer 116 is complete, a first poly layer 108 is deposited on the structured oxide layer 116, as shown in FIG. 2J. The first poly layer 108 can be polysilicon or any other appropriate conductive gate material. The first poly layer 108 can form, for example, the floating gates of the memory cell.

A thin oxide layer 112 can be formed on top of the first poly layer 108 and a second poly layer 110 is deposited on the thin oxide layer 112, as shown in FIG. 2K. The thin oxide layer 112 can be, for example, oxide-nitride-oxide or any other appropriate dielectric. The second poly layer 110 can be, for example, polysilicon or any other appropriate gate material.

In some implementations, the first poly layer 108 and the second poly layer 110 can both be etched in a single etching process to form gates for the select transistor 104 and memory transistor 106. The resulting select transistor 104 and memory transistor 106 will have defined floating gates (e.g., first poly layer 108) and control gates (e.g., second poly layer 110). In some implementations, the first poly layer 108 and the second poly layer 110 that form the gates for the select transistor 104 can be connected. This enables the select transistor to operate as a single gate transistor.

In some implementations, the first poly layer 108 can be etched prior to deposition of the second poly layer 110 to form the floating gates. In these implementations, the second poly layer 110 can be deposited on the semiconductor substrate 102 and the thin oxide layer 112 that is deposited on the first poly layer 108.

### §2.4 Example Source and Drain Formation

Source 118 and drain 120 formation can be performed by adding dopants 220 to the semiconductor substrate 102, as shown in FIG. 2L. In some implementations, the memory cell 100 can have a source 120 that is common to the select transistor 104 and memory transistor 106, as shown in FIG. 1.

In some implementations, a source 118 and drains 120 are formed after the gates 108, 110 have been formed to create self-aligned gates. When the source 118 and drains 120 are formed after gate formation, dopants can be added to the semiconductor substrate 102, for example, at a position adjacent to the select transistor 104 and memory transistor 106, respectively. The dopants can be added by ion implantation or any other appropriate method for adding dopants to a semiconductor substrate 102. In these implementations, the gates 108, 110 of the select transistor 104 and memory transistor 106 function as masks to prevent dopants from being added to the semiconductor substrate 102 beneath the respective gates 108, 110. Accordingly, the select transistors 104 and the memory transistors 106 can be self-aligned transistors.

### §3.0 Example Process Flow

### §3.1 Example Substrate Decontamination and Repair

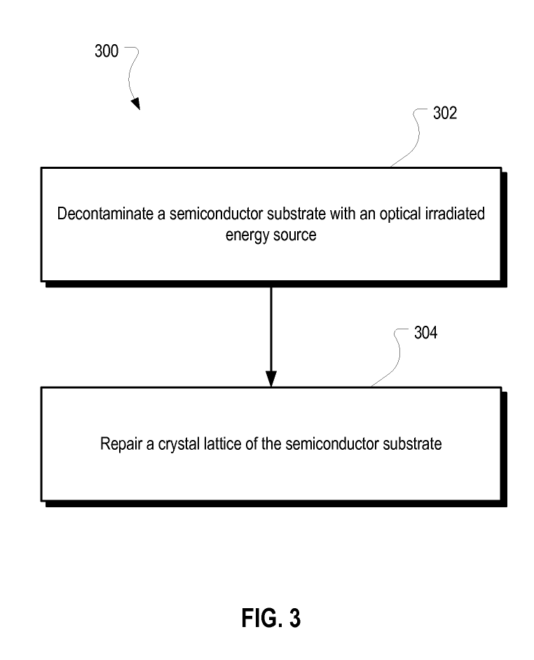

FIG. 3 is a flow chart of an example process 300 of decontaminating and repairing a semiconductor substrate (e.g., semiconductor substrate 102 of FIG. 2H). The process 300 can be implemented, for example, in a rapid thermal processing unit.

Stage 302 decontaminates a semiconductor substrate with an optical irradiated energy source. In some implementations, decontamination can include exposing the semiconductor substrate (e.g., semiconductor substrate 102 of FIG. 2H) to an optical irradiated energy source having energy sufficient to break a molecular bond of a contaminant on the semiconductor substrate. For example, energies of about 347 kJ/mol, 413 kJ/mol, and 301 kJ/mol can be used to break a C—C bond, a C—H bond, and a Si—C bond, respectively. The semiconductor substrate can be exposed to the optical irradiated energy source, for example, in a rapid thermal processing unit including an optical irradiated energy source.

Stage 304 repairs a crystal lattice of the semiconductor substrate (e.g., semiconductor substrate 102 of FIG. 2H). In some implementations, the semiconductor substrate can be exposed to an atmosphere for a period of time and at a temperature that is sufficient to recrystallize the crystal lattice to repair the crystal lattice. For example, a silicon substrate can recrystallize when it is exposed to about 1150 degrees Celsius for approximately 10 to 15 seconds. The semiconductor substrate can be exposed to the atmosphere, for example, in a rapid thermal processing unit.

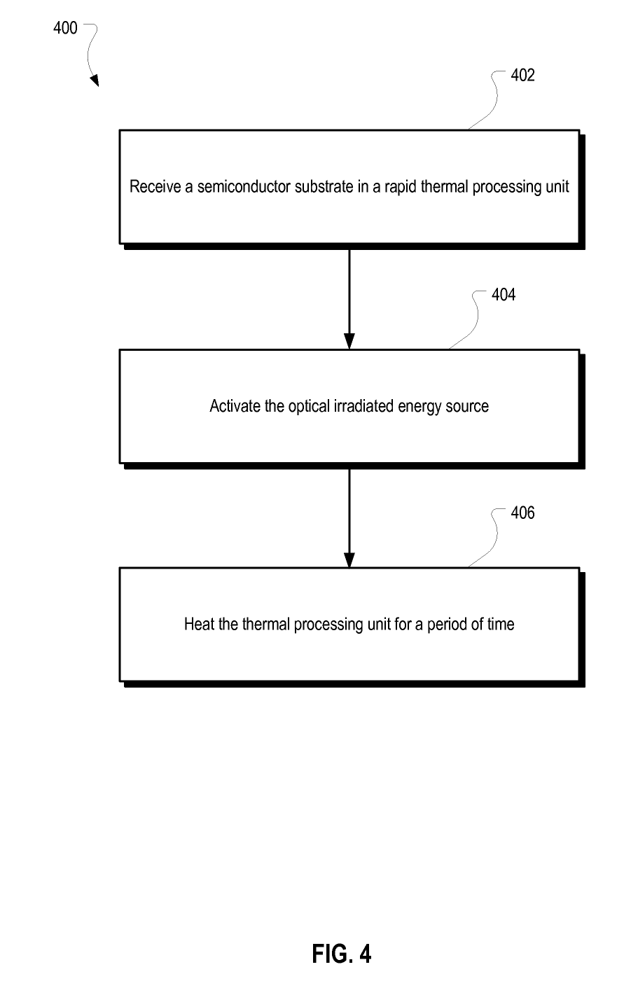

FIG. 4 is a flow chart of another example process 400 of decontaminating and repairing a semiconductor substrate (e.g., semiconductor substrate 102 of FIG. 2H). The process 400 can be implemented, for example, in a rapid thermal processing unit.

Stage 402 receives a semiconductor substrate in a rapid thermal processing unit. In some implementations, the rapid thermal processing unit can include an optical irradiated energy source. The optical irradiated energy source can include, for example, an ultraviolet energy source and an infrared energy source.

Stage 404 activates the optical irradiated energy source. In some implementations, the optical irradiated energy source can provide an energy sufficient to break a molecular bond of a contaminant on the semiconductor substrate (e.g., semiconductor substrate 102 of FIG. 2H). For example, predefined energies of about 347 kJ/mol, 413 kJ/mol, and 301 kJ/mol can be used to break a C—C bond, a C—H bond, and a Si—C bond, respectively. The semiconductor substrate can be exposed to the optical irradiated energy source, for example, in a rapid thermal processing unit including an optical irradiated energy source.

Stage 406 heats the thermal processing unit for a period of time. In some implementations, the thermal processing unit is heated at least a temperature that is sufficient to recrystallize the crystal lattice of the semiconductor substrate (e.g., semiconductor substrate 102 of FIG. 2H). For example, a silicon substrate can recrystallize when it is exposed to at least about 1000 degrees Celsius. The semiconductor substrate can be exposed to the atmosphere, for example, in a rapid thermal processing unit.

### §3.2 Example Memory Cell Fabrication

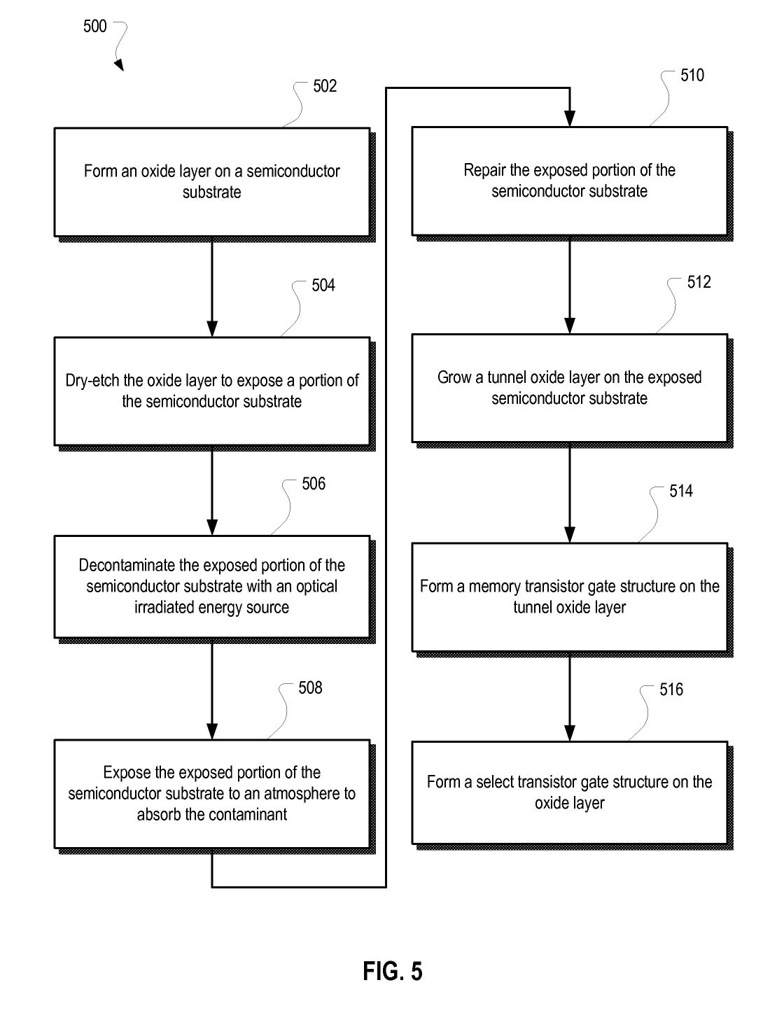

FIG. 5 is a flow chart of an example process 500 of fabricating a memory cell (e.g., memory cell 100 of FIG. 1). Stage 502 forms an oxide layer (e.g., oxide layer 202 of FIG. 2A) on the semiconductor substrate (e.g., semiconductor substrate 102 of FIG. 2A). In some implementations, the oxide layer can have a substantially uniform thickness. In some implementations, the oxide layer can have a raised oxide portion (e.g., raised oxide portion 124 of FIG. 2C). The oxide layer can be formed, for example, by growing a first oxide layer (e.g., oxide layer 202), etching the first oxide layer to define the raised oxide portion (e.g., the remaining portion 202a of the initial oxide layer 202 of FIG. 2B), and growing a second oxide layer (e.g., oxide layer 206 of FIG. 2C). In some implementations, the oxide can be grown through a thermal oxidation process in an oxidation chamber.

Stage 504 dry-etches the oxide layer to expose a portion (e.g., portion 208c of FIG. 2G) of the semiconductor substrate. In some implementations, the dry-etching can remove the oxide layer to form a tunnel window (e.g., tunnel window 208a of FIG. 2E). In some implementations, the dry-etching can be performed with a plasma etching system that directs plasma ions at the oxide layer.

Stage 506 decontaminates the exposed portion (e.g., portion 208c of FIG. 2G) of the semiconductor substrate with an optical irradiated energy source (e.g., optical irradiated energy source 211 of FIG. 2H). In some implementations, the decontamination can be performed by exposing the exposed portion of the semiconductor substrate to the optical irradiated energy source. The optical irradiated energy source can produce at least a predefined energy that is sufficient to break a molecular bond of a contaminant on the exposed portion of the semiconductor substrate. For example, predefined energies of 347 kJ/mol, 413 kJ/mol, and 301 kJ/mol can be used to break a C—C bond, a C—H bond, and a Si—C bond, respectively. The exposed portion of the semiconductor substrate can be decontaminated, for example, by a rapid thermal processing unit.

Stage 508 exposes the exposed portion (e.g., portion 208c of FIG. 2G) of the semiconductor substrate to an atmosphere to absorb the contaminant. In some implementations, the atmosphere can have at least a predefined temperature to facilitate absorption of the contaminant into the atmosphere. For example, the predefined temperature can be 1000 degrees Celsius. The exposed portion of the semiconductor substrate (e.g., semiconductor substrate 102 of FIG. 2H) can be exposed to the atmosphere, for example, by a rapid thermal processing unit.

Stage 510 repairs the exposed portion (e.g., portion 208c of FIG. 2G) of the semiconductor substrate (e.g., semiconductor substrate 102 of FIG. 2H). In some implementations, the semiconductor substrate can be repaired by exposing the exposed portion of the semiconductor substrate to at least a predefined temperature. In some implementations, the predefined temperature can have a magnitude that is sufficient to repair damaged lattice of the semiconductor substrate. For example, a silicon substrate can be repaired by exposing the silicon substrate to a temperature of at least about 1000 degrees Celsius for approximately 10 to 15 seconds. The exposed portion of the semiconductor substrate can be repaired, for example, by a rapid thermal processing unit.

Stage 512 grows a tunnel oxide layer (e.g., tunnel oxide layer 214 of FIG. 2I) on the exposed portion (e.g. portion 208c) of the semiconductor substrate. In some implementations, the tunnel oxide layer can be grown to have a thickness between about 19 Å-90 Å. The tunnel oxide layer can be grown, for example, in an oxidation chamber.

Stage 514 forms a memory transistor gate structure (e.g., memory transistor gate structure 109 of FIG. 1) on the tunnel oxide layer. The memory transistor gate can be formed, for example, by depositing polysilicon (e.g., poly 108 and/or 110 of FIG. 1) on the semiconductor substrate and etching the polysilicon to define the gate. The memory transistor gate can include a floating gate (e.g., poly 108 of FIG. 1).

Stage 516 forms a select transistor gate (e.g., select transistor gate structure 107 of FIG. 1) on the oxide layer. In some implementations, the select transistor gate can be formed near the memory transistor gate so that the select transistor (e.g., select transistor 104 of FIG. 1) and memory transistor (e.g., memory transistor 106 of FIG. 1) can share a common source (e.g., source 118 of FIG. 1) or drain. The select transistor gate can be formed, for example, by depositing polysilicon (e.g., poly 108 and/or 110 of FIG. 1) on the semiconductor substrate and etching the polysilicon to define the gate.

While this document contains many specific implementation details, these should not be construed as limitations on the scope of what may be claimed, but rather as descriptions of features that may be specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while process steps are depicted in the drawings in a particular order, this should not be understood as requiring that such process steps be performed in the particular order shown or in sequential order, or that all illustrated process steps be performed, to achieve desirable results.

Particular embodiments of the subject matter described in this specification have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results.

What is claimed is:

1. A method, comprising:
forming an oxide layer on a semiconductor substrate;
dry-etching the oxide layer to expose a portion of the semiconductor substrate;
decontaminating the exposed portion of the semiconductor substrate with an optical irradiated energy source; and
repairing the exposed portion of the semiconductor substrate.

2. The method of claim 1, wherein decontaminating comprises exposing the exposed portion of the semiconductor substrate to the optical irradiated energy source, the optical irradiated energy source being operable to generate an energy level that is sufficient to break a molecular bond of a contaminant on the exposed portion of the semiconductor substrate.

3. The method of claim 2, wherein the decontaminating further comprises exposing the exposed portion of the semiconductor substrate to an atmosphere comprising less than about 50 parts per million of oxygen to absorb the contaminant.

4. The method of claim 3, wherein the atmosphere is maintained at a temperature sufficient to absorb the contaminant.

5. The method of claim 1, wherein repairing comprises exposing the exposed portion of the semiconductor substrate to an atmosphere having a temperature that is sufficient to repair damaged lattice of the semiconductor substrate.

6. The method of claim 5, further comprising removing the semiconductor substrate from the atmosphere after a period of time.

7. The method of claim 6, wherein the time is between 10 and 15 seconds.

8. The method of claim 7, wherein the temperature is at least about 1000 degrees Celsius.

9. The method of claim 1, further comprising:
growing a tunnel oxide layer on the exposed semiconductor substrate; and
forming a memory transistor gate on the tunnel oxide layer.

10. The method of claim 1, wherein forming the oxide layer comprises:
growing a first oxide layer on the semiconductor substrate;
etching the first oxide layer to define a raised oxide portion; and
growing a second oxide layer on the semiconductor substrate and the remaining first oxide layer.

11. The method of claim 1, further comprising forming a select transistor gate on the oxide layer.

12. A non-volatile memory cell, comprising:
an oxide layer formed on a semiconductor substrate;
a dry-etched tunnel window formed in the oxide layer, the dry-etched tunnel window having a diameter less than 10 nanometers; and
a gate structure formed on top of the tunnel window

13. The non-volatile memory cell of claim 12, wherein the gate structure comprises a self-aligned gate structure, the gate structure comprising a floating gate and a control gate associated with a memory transistor.

14. The non-volatile memory cell of claim 13, further comprising a first poly layer deposited on the semiconductor substrate and a second poly layer deposited on top of the first poly layer, wherein the first poly layer and second poly layer are associated with a select transistor, and wherein the first poly layer and the second poly layer are connected.
